(19) United States
(12) Patent Application Publication
(10) Pub. No.: US 2010/0052021 A1
(43) Pub. Date: Mar. 4, 2010

(54) SEMICONDUCTOR MEMORY DEVICE

(76) Inventor: Yoshinobu MOCHO, Toyama (JP)

Correspondence Address: MCDERMOTT WILL & EMERY LLP, 600 13TH STREET, NW, WASHINGTON, DC, 20005-3096, US

(21) Appl. No.: 12/501,744

(22) Filed: Jul. 13, 2009

(30) Foreign Application Priority Data
Aug. 26, 2008 (JP) 2008-216654

(51) Int. Cl. H01L 29/94; H01L 29/43

(52) U.S. Cl. 257/295; 257/306; 257/E29.345; 257/E29.139

(57) ABSTRACT

A semiconductor memory device includes: a MOS transistor; a bit line provided above a memory region, and electrically connected to an impurity diffusion layer; a capacitor which has a capacitive insulating film including a ferroelectric material or a high-k material, and is provided at a position higher than that of the bit line; a lower hydrogen barrier film which covers a lower side of the capacitor; an upper hydrogen barrier film which covers lateral and upper sides of the capacitor; an interconnect formed above a peripheral circuit region; and a conductive layer which is formed at a position lower than that of the bit line, and extends from the memory region to the peripheral circuit region when viewed from above, for electrically connecting the bit line and the interconnect to each other.

### CROSS-REFERENCE TO RELATED APPLICATIONS

This application claims priority from Japanese Patent Application No. 2008-216654 filed on Aug. 26, 2008, the disclosure of which application is hereby incorporated by reference into this application in its entirety for all purposes.

### BACKGROUND

The technique disclosed in the specification relates to semiconductor memory devices. More particularly, the technique disclosed in the specification relates to a semiconductor memory device which includes capacitors made of a ferroelectric material or a high-k (high dielectric constant) material, and formed at a position higher than bit lines.

Since a capacitor having a capacitive insulating film made of a high-k material provides large electrostatic capacitance with a small area, the use of such a capacitor for a DRAM (Dynamic Random Access Memory) can significantly reduce the circuit area. Moreover, since a capacitive insulating film made of a ferroelectric material exhibits hysteresis characteristics due to the remnant polarization, and has a high relative dielectric constant, semiconductor memory devices, such as DRAMs, including capacitors having a capacitive insulating film made of silicon oxide or silicon nitride, may be replaced with semiconductor memory devices including capacitors having such a capacitive insulating film.

However, since a ferroelectric material or a high-k material is an oxide whose crystal structure itself determines its physical characteristics, the crystal structure changes when in contact with hydrogen having a reducing function, thereby significantly changing physical characteristics such as hysteresis characteristics, a dielectric constant, and the like. On the other hand, the steps of forming MOS (Metal Oxide Semiconductor) transistors, forming multilayer interconnects, forming a protective film, and the like often use a large amount of a silane gas, a resist material, water (moisture), and the like, containing hydrogen atoms, in addition to a hydrogen gas. Thus, it is necessary to protect the capacitive insulating film from hydrogen and the like, which are generated during the manufacturing process of the semiconductor memory device.

Thus, recently, there has been proposed a technique of providing a hydrogen barrier film around capacitors so as to cover a plurality of capacitors one by one, or to collectively cover all the capacitors as one unit, with the hydrogen barrier film (see, for example, Japanese Published Patent Application No. 2007-165439).

A semiconductor memory device having a capacitive insulating film made of a ferroelectric material, which is disclosed in Japanese Published Patent Application No. 2007-165439, will be described below as a first conventional example with reference to FIG. 8.

FIG. 8 is a cross-sectional view showing the semiconductor memory device of the first conventional example. As shown in the figure, the semiconductor memory device of the first conventional example is a ferroelectric memory 1 which includes a driving device portion 3 formed in a substrate 4, and a ferroelectric capacitor 2 provided at a position higher than that of the driving device portion 3, with a first interlayer insulating film 6 interposed therebetween. The ferroelectric capacitor 2 is formed by a lower electrode 8 and an upper electrode 10, and a ferroelectric material layer 9 interposed between the pair of electrodes. Moreover, a first conductive portion 12, which electrically connects the driving device portion 3 and the lower electrode 8 to each other, extends through the first interlayer insulating film 6, and a first hydrogen barrier film 7 is provided between the first interlayer insulating film 6 and the lower electrode 8, except for a portion on the first conductive portion 12. A second conductive portion 20, which is provided in a second interlayer insulating film 14, is connected to the upper electrode 10 of the ferroelectric capacitor 2, and the upper and side surfaces of the ferroelectric capacitor 2 are covered by a second hydrogen barrier film 13 except for a connection portion between the upper electrode 10 and the second conductive portion 20.

In this semiconductor memory device, the ferroelectric material layer 9 is less likely to be reduced by hydrogen in a heat treatment process in a hydrogen atmosphere when forming interconnects, a protective film, and the like, due to the first hydrogen barrier film 7 and the second hydrogen barrier film 13, whereby reliability is improved.

On the other hand, as a technique of improving the integration level, a COB (Capacitor Over Bit line) structure has been commonly proposed in semiconductor memory devices represented by DRAMs, (see, for example, Japanese Published Patent Application No. H09-321242). A semiconductor memory device of a second conventional example disclosed in Japanese Published Patent Application No. H09-321242 will be described below with reference to FIG. 9.

FIG. 9 is a cross-sectional view showing the semiconductor memory device of the second conventional example. In the semiconductor memory device of the second conventional example, bit lines BL₁, BL₂ for writing and reading data are connected to one of semiconductor regions (a source region and a drain region) of each memory cell select transistor. This conventional example has a so-called COB structure in which the bit lines BL₁, BL₂ are positioned at a height between the memory cell select transistors and capacitive elements C. Since the COB structure requires no contact plug between the capacitive elements, the cell area can be reduced accordingly, as compared to a CUB (Capacitor Under Bit line) structure in which bit lines are provided above capacitive elements. Thus, the COB structure is characterized by being advantageous in terms of improving the integration level.

### SUMMARY

However, in the case where the first conventional example and the second conventional example are combined to obtain both effects of preventing degradation of the capacitive insulating film, and of reducing the cell area, as shown in FIG. 10A, the COB structure is formed while having the structure in which the ferroelectric capacitor 2 is covered by the first hydrogen barrier film 7 and the second hydrogen barrier film 13. Thus, the steps of processing the ferroelectric capacitor 2, and the first hydrogen barrier film 7 and the second hydrogen barrier film 13 are performed after forming the bit lines.

Thus, as shown in FIGS. 10B and 10C, bit lines 32 are simultaneously etched by overetching that is performed when processing the first hydrogen barrier film 7 and the second hydrogen barrier film 13 by using a hard mask 33 or a resist mask 40. When the bit lines 32 are etched, the film thickness thereof is reduced, resulting in an increased resistance of the bit lines 32. This causes problems of a malfunction due to a change in delay factor of circuits, and defective reading due to a change in ratio of the bit line capacitance to the amount of charge held by the capacitor.

Thus, a semiconductor memory device disclosed in the specification has a COB structure, in which degradation of a capacitive insulating film by hydrogen is prevented, and reduction in film thickness of bit lines in an etching step is prevented, whereby a malfunction of circuits and defective reading of the memory, due to an increased resistance of the bit lines, can be suppressed.

A semiconductor memory device according to an example of the present invention includes: a semiconductor substrate in which a memory region, and a peripheral circuit region adjacent to the memory region, are formed; a MOS transistor formed on the memory region, and having a gate electrode formed over the semiconductor substrate, and first and second impurity diffusion layers formed in regions which are located on both lateral sides of the gate electrode in an upper part of the semiconductor substrate; a bit line provided above the memory region, and electrically connected to the first impurity diffusion layer; a capacitor which includes a lower electrode, an upper electrode, and a capacitive insulating film interposed between the lower electrode and the upper electrode, and including a ferroelectric material or a high-k material, the capacitor being provided above the memory region at a position higher than that of the bit line; a lower hydrogen barrier film which is formed between the bit line and the capacitor, and covers a lower side of the capacitor; an upper hydrogen barrier film which covers lateral and upper sides of the capacitor, and is directly connected to the lower hydrogen barrier film in a region which surrounds the capacitor when viewed from above; a first interconnect formed above the peripheral circuit region; and a conductive layer which is formed at a position lower than that of the bit line, and extends from the memory region to the peripheral circuit region when viewed from above, for electrically connecting the bit line and the first interconnect to each other.

According to this structure, since the lower hydrogen barrier film and the upper hydrogen barrier film entirely surround the capacitor, the capacitive insulating film can be prevented from being reduced by hydrogen during the manufacturing process, whereby a change in physical characteristics of the capacitive insulating film can be suppressed. Moreover, since the bit line is electrically connected to the first interconnect located above the peripheral circuit region, through the conductive film formed at a position lower than that of the bit line, the bit line is not exposed in the etching steps for forming the lower hydrogen barrier film and the upper hydrogen barrier film, whereby reduction in film thickness of the bit line can be prevented. Thus, the resistance of the bit line can be prevented from becoming higher than a set value, whereby reliability of the semiconductor memory device can be improved.

Multiple ones of the capacitor may be provided, and arranged in a matrix pattern over the memory region, and the lower hydrogen barrier film and the upper hydrogen barrier film may collectively surround all of the multiple ones of the capacitor.

The conductive layer may be a third impurity diffusion layer formed in the upper part of the semiconductor substrate. In this case, the third impurity diffusion layer can be formed simultaneously with the first and second impurity diffusion layers.

The conductive layer may be a second interconnect provided at a position lower than that of the bit line.

The conductive layer may be an electrode interconnect formed in a same layer as that of the gate electrode. In this case, the electrode interconnect can be formed simultaneously with the gate electrode.

The semiconductor memory device may further include an interlayer insulating film formed on lateral and upper sides of the capacitor, a groove may be formed in a portion of the interlayer insulating film, which is located above a boundary region between the memory region and the peripheral circuit region, and the upper hydrogen barrier film may be formed so as to extend from an upper surface of the interlayer insulating film to an inner surface of the groove.

In the case where the lower electrode is electrically connected to the second impurity diffusion layer, the semiconductor memory device is a so-called DRAM or a FeRAM (Ferroelectric Random Access Memory).

Preferably, the lower hydrogen barrier film is made of an insulating material.

Preferably, the upper hydrogen barrier film and the lower hydrogen barrier film are in contact with each other at a position right above the conductive layer.

### BRIEF DESCRIPTION OF THE DRAWINGS

FIG. 1 is a cross-sectional view showing a main part of a semiconductor memory device according to an embodiment of the present invention.

FIG. 2 is a plan view showing a main part of the semiconductor memory device according to the embodiment of the present invention.

FIG. 3 is a cross-sectional view showing a main part of a semiconductor memory device according to a first modification of the embodiment of the present invention.

FIG. 4 is a cross-sectional view showing a main part of a semiconductor memory device according to a second modification of the embodiment of the present invention.

FIG. 5 is a cross-sectional view showing a main part of a semiconductor memory device according to a third modification of the embodiment of the present invention.

FIG. 6 is a cross-sectional view showing a main pair of a semiconductor memory device according to a fourth modification of the embodiment of the present invention.

FIGS. 7A, 7B, 7C, 7D, 7E, 7F, and 7G are cross-sectional views showing a manufacturing method of the semiconductor memory device according to the embodiment of the present invention.

FIG. 8 is a cross-sectional view showing a semiconductor memory device according of a first conventional example.

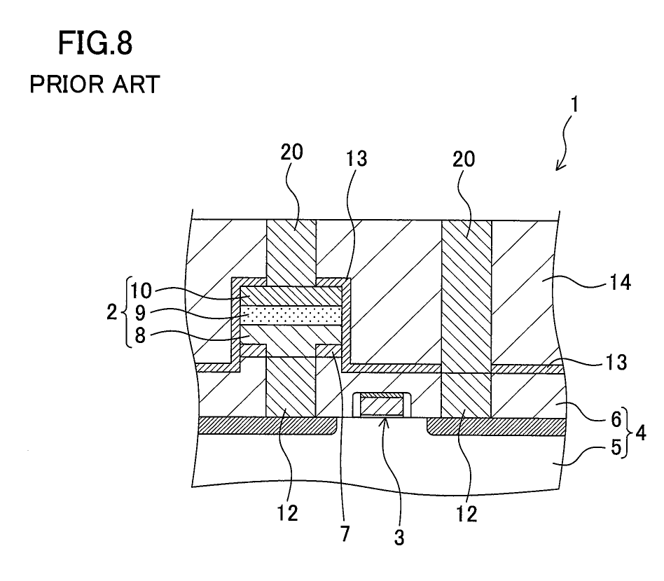

FIG. 9 is a cross-sectional view showing a semiconductor memory device according to a second conventional example.

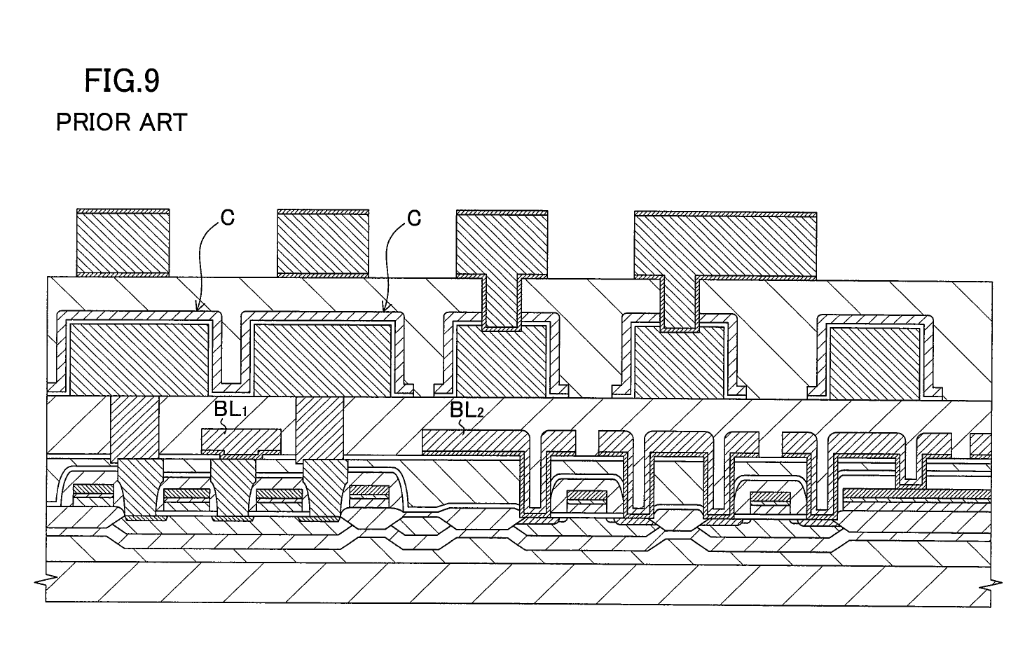

FIGS. 10A, 10B, and 10C are cross-sectional views illustrating problems which occur in a COB-type semiconductor memory device in which the first and second conventional examples are combined.

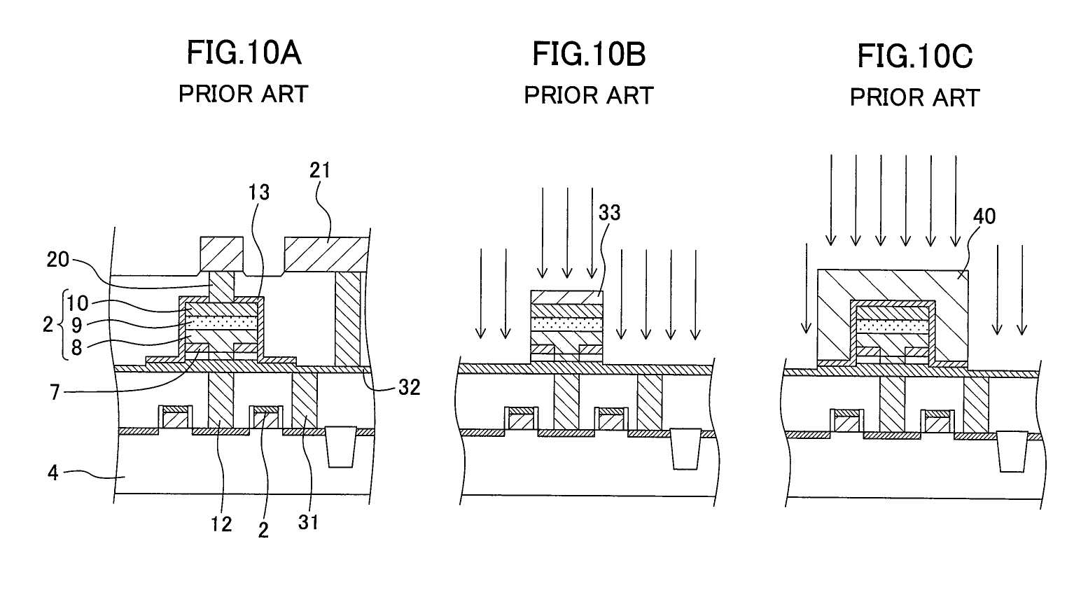

### DETAILED DESCRIPTION

An embodiment of the present invention will be described below with reference to the accompanying drawings.

### Embodiment

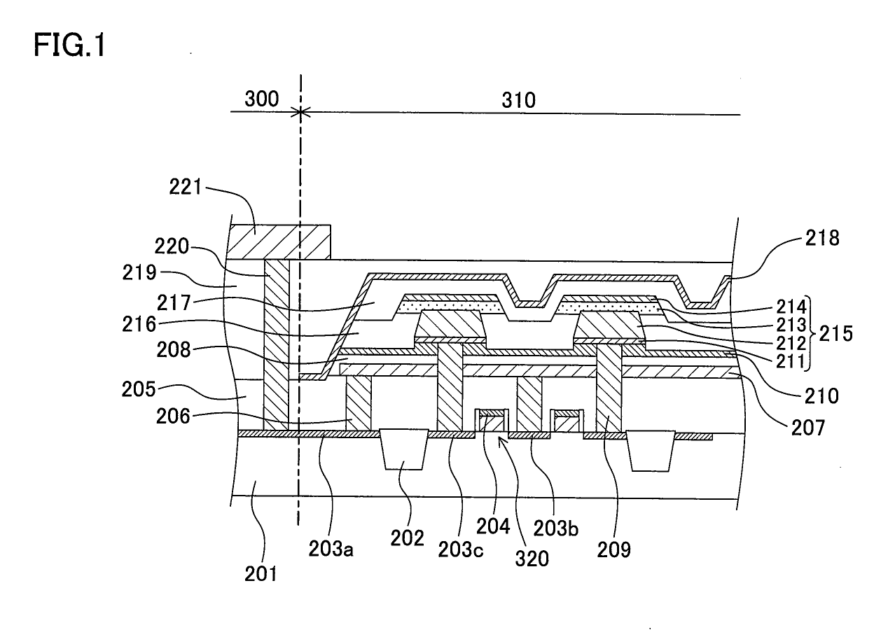

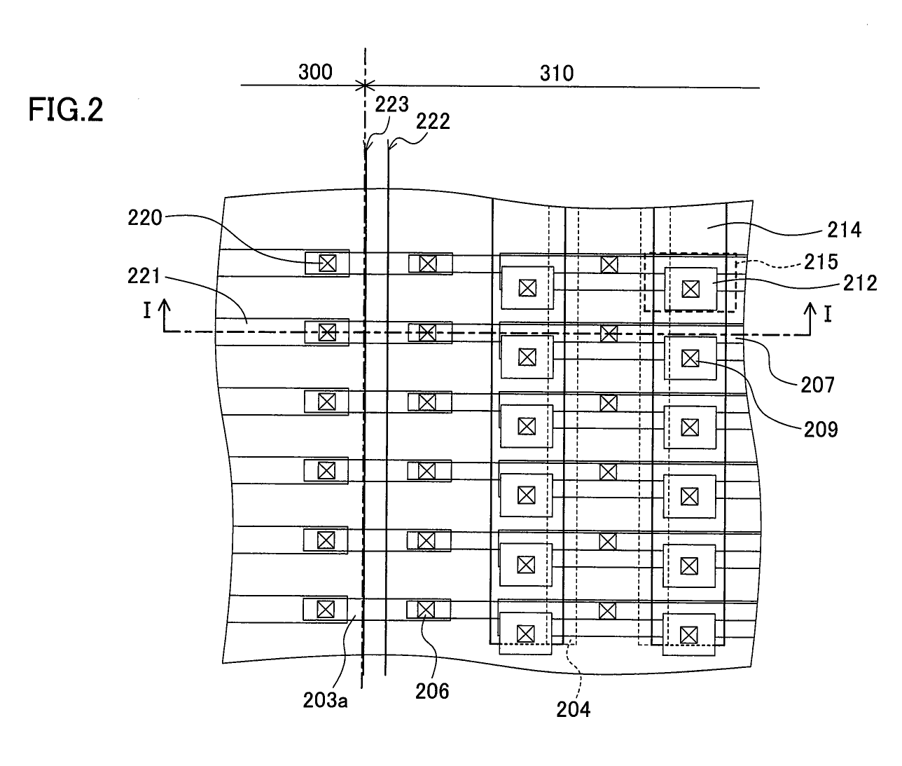

FIG. 1 is a cross-sectional view of a boundary region between a memory region and a peripheral circuit region of a semiconductor memory device according to an embodiment of the present invention, and FIG. 2 is a plan view showing the boundary region of the semiconductor memory device of the present embodiment. FIG. 1 shows a cross-sectional structure taken along line I-I in FIG. 2. FIG. 2 shows also members provided under upper electrodes 214 and interconnects 221 in order to facilitate explanation.

As shown in FIGS. 1 and 2, the semiconductor memory device of the present embodiment includes: a semiconductor substrate 201 in which a peripheral circuit region 300 and a memory region 310 are formed; memory cells arranged in, for example, a matrix pattern on the memory region 310 of the semiconductor substrate 201; and bit lines 207 connected to the memory cells. Each memory cell includes: a MOS transistor (a cell select transistor) 320 having a gate electrode 204 formed on the semiconductor substrate 201 with, for example, a gate insulating film interposed therebetween, and impurity diffusion layers 203b, 203c including n-type impurities, which are formed in regions located on both lateral sides of the gate electrode 204; and a capacitor 215 formed above the semiconductor substrate 201, and having a conductive second lower hydrogen barrier film 211, a lower electrode 212, an upper electrode 214, and a capacitive insulating film 213 interposed between the lower electrode 212 and the upper electrode 214. The capacitive insulating film 213 is made of, for example, a high-k material or a ferroelectric material, such as a perovskite-type oxide, having, for example, the general formula Pb(ZrₓTi₁₋ₓ)O₃, (BaₓSr₁₋ₓ)TiO₃, or (BiₓLa₁₋ₓ)₄Ti₃O₁₂ (where x is 0≦x≦1 in each formula), or the like. Note that a high-k film or a ferroelectric film may be provided in a part of the capacitive insulating film 213. The structure of the semiconductor memory device of the present embodiment will be described in more detail below.

A first interlayer insulating film 205, which embeds the MOS transistors 320, is provided over the semiconductor substrate 201, and a plurality of bit lines 207 are provided on the first interlayer insulating film 205. Moreover, impurity diffusion layers 203a, which are separated from the impurity diffusion layers 203c by an element isolation region 202, is provided in a region from the memory region 310 to the peripheral circuit region 300 in the semiconductor substrate 201. The bit lines 207 are respectively connected to the impurity diffusion layers 203a through first contact plugs 206 extending through the first interlayer insulating film 205. Moreover, above the memory region 310, a second interlayer insulating film 208 is provided on the first interlayer insulating film 205 and the bit lines 207. An insulating first lower hydrogen barrier film 210 is provided on the second interlayer insulating film 208. The first lower hydrogen barrier film 210 is made of, for example, silicon nitride having a low hydrogen permeability, or the like.

The conductive second lower hydrogen barrier films 211 are provided on the first lower hydrogen barrier film 210. The lower electrode 212, the capacitive insulating film 213, and the upper electrode 214 are sequentially provided on each of the second lower hydrogen barrier films 211 from bottom to top in this order. The lower electrodes 212 are respectively connected to the impurity diffusion layers 203c of the MOS transistors 320 through second contact plugs 209 which extend through the first interlayer insulating film 205, the second interlayer insulating film 208, and the first lower hydrogen barrier film 210. Above the memory region 310, a third interlayer insulating film 216, which embeds the outer peripheries of the second lower hydrogen barrier films 211 and the outer peripheries of the lower electrodes 212, is provided over the second interlayer insulating film 208 and the first lower hydrogen barrier film 210. A fourth interlayer insulating film 217 is provided on the third interlayer insulating film 216 and the upper electrodes 214. The second interlayer insulating film 208, the third interlayer insulating film 216, and the fourth interlayer insulating film 217 have tapered side surfaces on the side of the boundary region between the peripheral circuit region 300 and the memory region 310. More specifically, these side surfaces of the second interlayer insulating films 208, the third interlayer insulating film 216, and the fourth interlayer insulating film 217 are tapered in the upward direction from the peripheral circuit region 300 toward the memory region 310, that is, tilted away from the boundary region in the direction from the peripheral circuit region 300 toward the memory region 310. Moreover, an upper hydrogen barrier film 218, which is in contact with the first lower hydrogen barrier film 210, is provided on the upper and side surfaces of the fourth interlayer insulating film 217, the respective side surfaces of the third interlayer insulating film 216 and the second interlayer insulating film 208, and the upper surface of the first interlayer insulating film 205 located near the boundary region. Although not shown in the figures, the first lower hydrogen barrier film 210 and the upper hydrogen barrier film 218 collectively surround all of the plurality of capacitors 215 formed on the memory region 310. In FIG. 2, reference character 222 denotes the boundary line of the first lower hydrogen barrier film 210 when viewed from above the substrate, and reference character 223 denotes the boundary line of the upper hydrogen barrier film 218 when viewed from above the substrate.

Moreover, a fifth interlayer insulating film 219 is provided on the first interlayer insulating film 205, which is formed on the peripheral circuit region 300, and the upper hydrogen barrier film 218. Interconnects 221 are provided on the fifth interlayer insulating film 219. The interconnects 221 on the peripheral circuit region 300 are respectively connected to the impurity diffusion layers 203a including n-type impurities, through third contact plugs 220 which extend through the fifth interlayer insulating film 219. With this structure, the bit lines 207 are electrically connected to circuits provided on the peripheral circuit region 300, such as a sense amplifier, through the first contact plugs 206, the impurity diffusion layers 203a, the third contact plugs 220, and the interconnects 221.

In the semiconductor memory device of the present embodiment, as described above, the first lower hydrogen barrier film 210 and the upper hydrogen barrier film 218 surround the capacitors 215 from all directions. The first lower hydrogen barrier film 210 and the upper hydrogen barrier film 218 may either collectively surround all of the plurality of capacitors 215, or surround each of the capacitors 215.

This structure can prevent hydrogen from entering from outside of the region surrounded by the first lower hydrogen barrier film 210 and the upper hydrogen barrier film 218. Thus, even when the capacitive insulating film 213 is made of a high-k material or a ferroelectric material, such as a metal oxide, physical characteristics of the capacitive insulating film 213 can be prevented from changing by a reduction process. Thus, in the case where the capacitive insulating film 213 is made of a ferroelectric material, a change in dielectric constant and in hysteresis characteristics, and the like can be suppressed, whereby degradation in performance as a non-volatile memory can be suppressed. Moreover, in the case where the capacitive insulating film 213 is made of a high-k material, a change in dielectric constant, and the like can be suppressed, whereby degradation in performance as a normal memory can be suppressed.

Moreover, in the semiconductor memory device of the present embodiment, the second interlayer insulating film 208 is provided between the bit lines 207 and the first lower hydrogen barrier film 210, and the second lower hydrogen barrier films 211 are provided directly on the first lower hydrogen barrier film 210. This structure prevents the bit lines 207 from being etched when forming the second lower hydrogen barrier films 211.

Moreover, in the semiconductor memory device of the present embodiment, the bit lines 207 are connected to the circuits provided on the peripheral circuit region 300, through conductive layers which extend from the memory region 310 to the peripheral circuit region 300, including the boundary region therebetween, when viewed from above the semiconductor substrate 201, and which are formed at a position lower than that of the bit lines 207. In the example shown in FIG. 1, the impurity diffusion layers 203a provided in the boundary region of the semiconductor substrate 201 are the above conductive layers. That is, the bit lines 207 are respectively connected to the interconnects 221, which are provided at a position higher than that of the capacitors 215, through the first contact plugs 206, the impurity diffusion layers 203a, and the third contact plugs 220, on the boundary region between the memory region 310 and the peripheral circuit region 300. Thus, in the semiconductor memory device of the present embodiment, the bit lines 207 are not exposed in the etching steps when forming the first lower hydrogen barrier film 210 and the second lower hydrogen barrier films 211, when forming the upper hydrogen barrier film 218, and the like, whereby the bit lines 207 are not etched. Therefore, an increase in interconnect resistance due to reduction in film thickness of the bit lines 207 does not occur, thereby enabling the semiconductor memory device of the present embodiment to perform as designed.

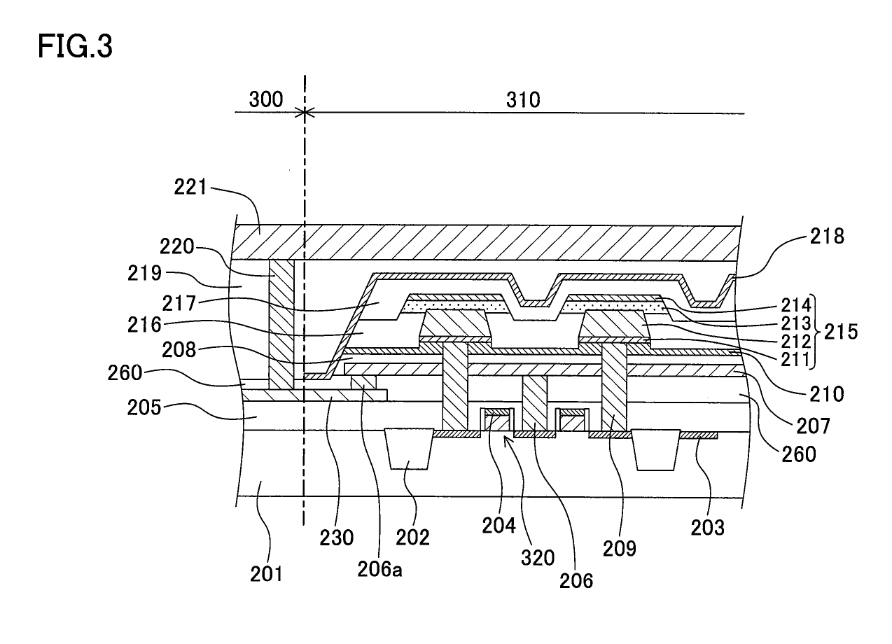

FIG. 3 is a cross-sectional view showing a semiconductor memory device of a first modification of the present embodiment. In FIG. 3, the impurity diffusion layers 203b, 203c shown in FIG. 1 are collectively shown as impurity diffusion layers 203. In the semiconductor memory device of the present embodiment shown in FIG. 1, the bit lines 207 and the interconnects 221 are electrically connected to each other through the impurity diffusion layers 203a formed in the boundary region between the memory region 310 and the peripheral circuit region 300. In this modification, on the other hand, the bit lines 207 and the interconnects 221 are electrically connected to each other through second interconnects 230, which are formed in an interconnect layer located at a position lower than that of the bit lines 207, and which are made of a tungsten film, a titanium film, and the like. First contact plugs 206a electrically connect the second interconnects 230 and the bit lines 207 to each other, and the third contact plugs 220 electrically connect the second interconnects 230 and the interconnects 221 to each other. Moreover, a fourth interlayer insulating film 260 is provided on the first interlayer insulating film 205 and the second interconnects 230, and a part of the upper hydrogen barrier film 218, and the bit lines 207 are provided on the fourth interlayer insulating film 260.

In such an interconnection method as well, the bit lines 207 and the second interconnects 230 are not etched in the etching steps for forming the first lower hydrogen barrier film 210 and the upper hydrogen barrier film 218. This can prevent an unintentional increase in interconnect resistance between the bit lines 207 and the interconnects 221 of the peripheral circuit region 300.

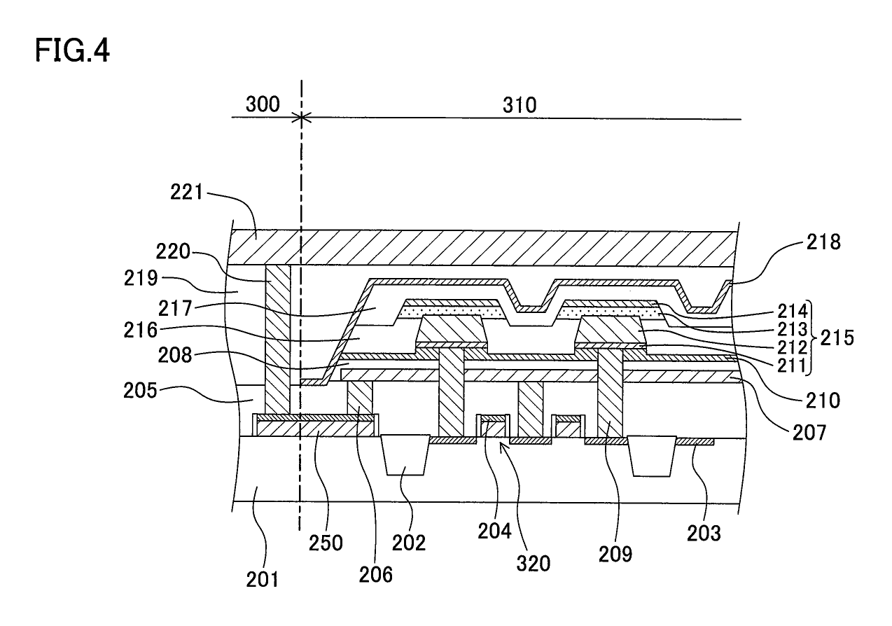

FIG. 4 is a cross-sectional view showing a semiconductor memory device of a second modification of the present embodiment. In the semiconductor memory device of this modification, the bit lines 207 are connected to the interconnects 221 through electrode interconnects 250 which are positioned on the boundary region between the peripheral circuit region 300 and the memory region 310 of the semiconductor substrate 201, and which are formed in the same layer as that of the gate electrodes 204 of the MOS transistors. The electrode interconnects 250 are made of, for example, polysilicon having its upper part silicided, like the gate electrodes 204, and are formed in the same step as that of the gate electrodes 204. In such an interconnection method as well, the bit lines 207 and the electrode interconnects 250 are not etched by the etching step for forming the upper hydrogen barrier film 218. Moreover, since the electrode interconnects 250 can be formed simultaneously with the gate electrodes 204, a reliable semiconductor memory device can be manufactured without increasing the number of steps.

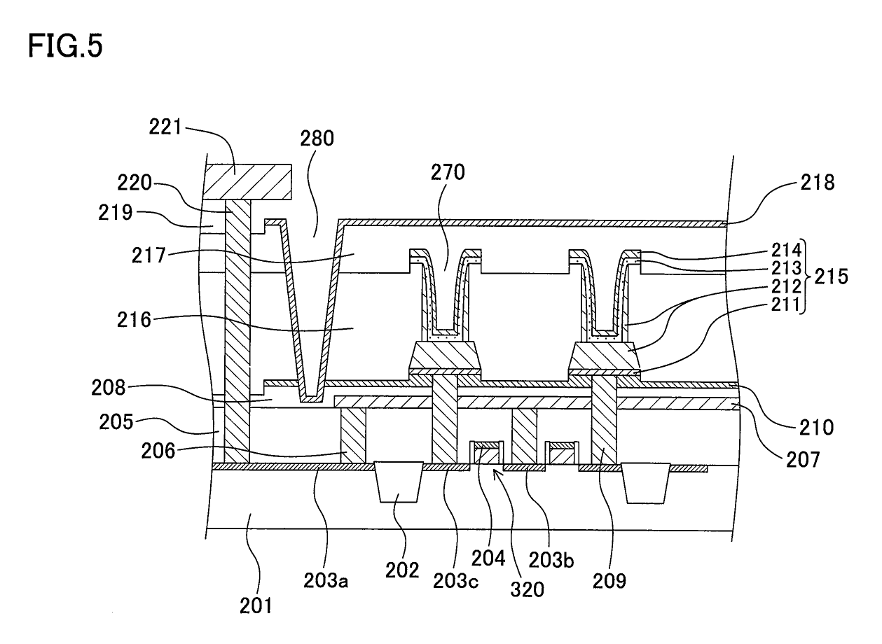

FIG. 5 is a cross-sectional view showing a semiconductor memory device of a third modification of the present embodiment. Although the capacitors 215 of the semiconductor memory devices shown in FIGS. 1, 3, and 4 are planar stacked capacitors, the capacitors 215 may be concave-type or convex-type three-dimensional capacitors, as shown in FIG. 5. In this case, the lower electrode 212 is provided also on the sidewalls of each first groove 270 formed in the third interlayer insulating film 216, and the capacitive insulating film 213 is formed on the lower electrode 212 in such a shape that extends along the inner surface of the first groove 270. Moreover, above the memory region 310, the upper hydrogen barrier film 218 is provided on the upper surface of the fourth interlayer insulating film 217, and on the inner surface of a second groove 280, which is formed from the third interlayer insulating film 216 to the fourth interlayer insulating film 217 and the second interlayer insulating film 208. In this case, since the upper hydrogen barrier film 218 is patterned on the fourth interlayer insulating film 217, the risk of etching the bit lines 207 during the processing can be reduced. Moreover, since the bit lines 207 and the interconnects 221 are electrically connected to each other through conductive layers which are located lower than the layer of the bit lines 207, reduction in film thickness of the bit lines 207 due to overetching when processing the insulating first lower hydrogen barrier film 210, and when forming the second groove 280 in the third interlayer insulating film 216 and the fourth interlayer insulating film 217, can be suppressed.

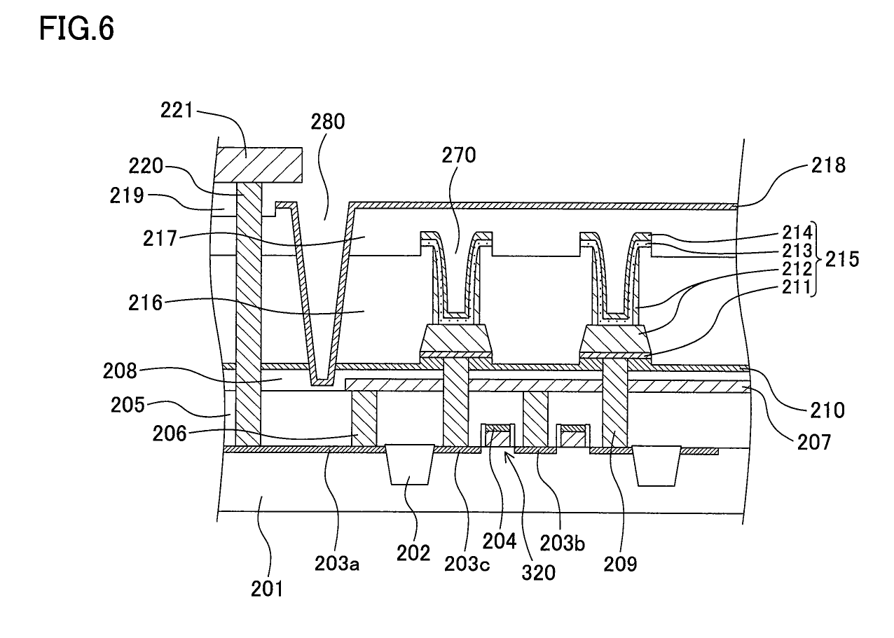

Note that the shape of the first lower hydrogen barrier film 210 and the upper hydrogen barrier film 218 is not limited to the shapes shown in FIGS. 1 through 5. The first lower hydrogen barrier film 210 and the upper hydrogen barrier film 218 may have any shape as long as the first lower hydrogen barrier film 210 and the upper hydrogen barrier film 218 surround the capacitors 215. For example, as shown in FIG. 6, the first lower hydrogen barrier film 210 may not be processed so that the first lower hydrogen barrier film 210 is left over the entire region of the substrate except for the second contact plugs 209 and the third contact plugs 220.

Note that, in the semiconductor memory devices of the modifications shown in FIGS. 5 and 6, when forming the second groove 280 in the third interlayer insulating film 216 and the fourth interlayer insulating film 217, formation of the second groove 280 may be stopped in the state where the second groove 280 does not extend through the first lower hydrogen barrier film 210, but exposes the upper surface of the first lower hydrogen barrier film 210.

Moreover, since the upper hydrogen barrier film 218 is not in contact with the conductive films including the bit lines 207, the upper hydrogen barrier film 218 may either be a conductive film or an insulating film.

Moreover, the semiconductor memory devices described above are configured so that the lower electrodes 212 of the capacitors 215 are respectively connected to the impurity diffusion layers 203c of the MOS transistors 320. However, the structure of the present invention is applicable also to a semiconductor memory device which is configured so that the lower electrodes 212 are respectively connected to the gate electrodes of the MOS transistors 320.

A manufacturing method of the semiconductor memory device of the present embodiment will be described below with reference to the figures.

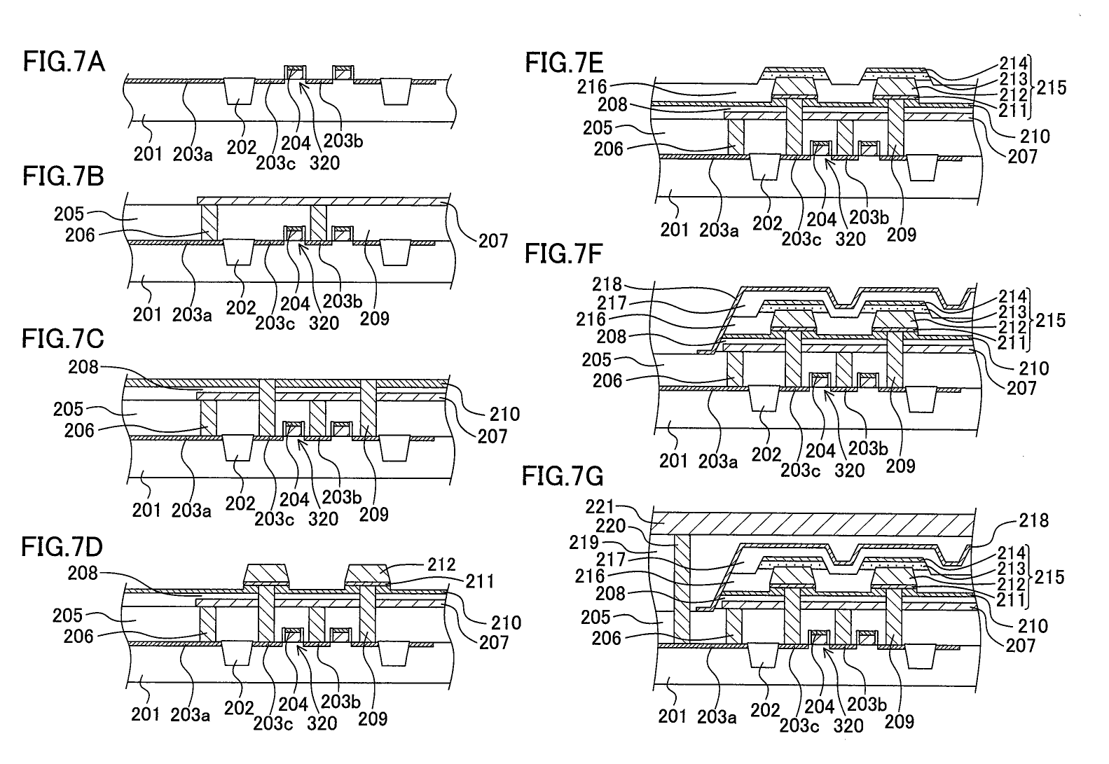

FIGS. 7A through 7G are cross-sectional views illustrating the manufacturing method of the semiconductor memory device of the present embodiment. First, as shown in FIG. 7A, grooves, having a depth of about 300 nm, are formed by a lithography method and a dry etching method in an upper part of a semiconductor substrate 201 which is made of, for example, P-type silicon. Then, a silicon oxide film is formed on the semiconductor substrate 201 by a CVD (Chemical Vapor Deposition) method. The silicon oxide film is then planarized by a CMP (Chemical Mechanical Polishing) method to selectively form element isolation regions 202, which are made of the silicon oxide embedded in the grooves. Then, a gate insulating film, having a thickness of about 10 nm, is formed on a principal surface (upper surface) of the semiconductor substrate 201 by, for example, a thermal oxidation method. Then, a polysilicon film, having a thickness of about 200 nm, is formed on the gate insulating film by a low pressure CVD method, and the polysilicon film formed is patterned by a lithography method and a dry etching method to form a plurality of polysilicon gate electrodes 204. Then, although not shown in the figures, a silicon oxide film, having a thickness of about 50 nm, is formed over the semiconductor substrate 201 by a CVD method so as to cover the gate electrodes 204, and an etchback process is performed to form a sidewall insulating film on the side surfaces of the gate electrodes 204. Then, by using the gate electrodes 204 and the sidewall insulating film as a mask, high concentration arsenic ions, for example, are implanted into the upper part of the semiconductor substrate 201 to form N-type impurity diffusion layers (drain diffusion layers) 203b and N-type impurity diffusion layers (source diffusion layers) 203c. MOS transistors are formed in this manner. Simultaneously with the impurity diffusion layers 203b, 203c, impurity diffusion layers 203a for interconnects are formed in the boundary region between a memory region and a peripheral circuit region in the semiconductor substrate 201.

Next, as shown in FIG. 7B, a silicon oxide film, which embeds the gate electrodes 204, is formed over the whole surface of the semiconductor substrate 201 by a CVD method, and the silicon oxide film is planarized by a CMP method so as to have a thickness of about 200 nm on the gate electrodes 204, thereby forming a first interlayer insulating film 205 made of silicon oxide. Then, contact holes, which extend through the first interlayer insulating film 205, and expose the impurity diffusion layers 203a, 203b, 203c, are formed by a lithography method and a dry etching method. Then, a titanium film having a thickness of about 10 nm, a titanium nitride film having a thickness of about 20 nm, and a tungsten film having a thickness of about 300 nm are sequentially deposited on the first interlayer insulating film 205 by a CVD method so as to fill the contact holes, and then, a portion of the deposited films, which remains on the first interlayer insulating film 205, is formed by a CMP method. Thus, first contact plugs 206, which are connected to the impurity diffusion layers 203a and the impurity diffusion layers 203b of the MOS transistors, are formed in the first interlayer insulating film 205. Then, a titanium film having a thickness of about 10 nm, and a tungsten film having a thickness of about 100 nm, are sequentially formed on the first interlayer insulating film 205 by a sputtering method. Then, the metal laminated film formed is patterned by a lithography method and a dry etching method to form bit lines 207 which are connected to the first contact plugs 206.

An example, in which silicon oxide is used as a constituent material of the first interlayer insulating film 205, was described above. More specifically, however, it is preferable to use so-called BPSG (Boron-Phospho-Silicate Glass) having boron (B) and phosphorus (P) added thereto, so-called HDP-NSG (High Density Plasma-Non Silicate Glass) formed by a high density plasma, and having neither boron nor phosphorus added thereto, or O₃-NSG using ozone (O₃) in an oxidizing atmosphere. Moreover, after the planarization process, the thickness of the first interlayer insulating film 205 on the gate electrodes 204 may be in the range of about 100 nm to about 500 nm.

Although an example, in which a P-type silicon substrate is used as the semiconductor substrate 201, and N-channel MOS transistors are formed on the semiconductor substrate 201, was described above, the present invention is effective also in the case where an N-type silicon substrate is used, and P-channel MOS transistors are formed on the N-type semiconductor substrate.

Next, as shown in FIG. 7C, a silicon oxide film is formed over the first interlayer insulating film 205 on the whole substrate surface including the bit lines 207 (the semiconductor memory device being fabricated) by, for example, a CVD method. Then, the silicon oxide film is planarized by a CMP method so as to have a thickness of about 100 nm on the bit lines 207, thereby forming a second interlayer insulating film 208 made of silicon oxide. Then, by a CVD method, a first lower hydrogen barrier film 210, made of silicon nitrogen, is formed with a thickness of about 100 nm on the second interlayer insulating film 208. Then, contact holes, which expose the impurity diffusion layers 203c of the MOS transistors, are formed by a lithography method and a dry etching method. Then, by a CVD method, a titanium film having a thickness of about 10 nm, a titanium nitride film having a thickness of about 20 nm, and a tungsten film having a thickness of about 300 nm, are sequentially formed on the first lower hydrogen barrier film 210 so as to fill the contact holes. Then, a portion of the formed metal laminated film, which is located outside the contact holes, is removed by a CMP method to form second contact plugs 209, which are connected to the impurity diffusion layers 203c of the MOS transistors, and extend through the first lower hydrogen barrier film 210, the second interlayer insulating film 208, and the first interlayer insulating film 205. Silicon oxide such as BPSG, HDP-NSG, O₃-NSG, or the like is similarly preferably used as a constituent material of the second interlayer insulating film 208. Moreover, after the planarizing process, the thickness of the second interlayer insulating film 208 on the bit lines 207 may be in the range of more than 0 nm up to about 500 nm. Note that, although a silicon nitride film having a thickness of about 100 nm was used as the first lower hydrogen barrier film 210, the present invention is not limited to this, and silicon oxynitride (SiON), aluminum oxide (Al₂O₃), titanium aluminum oxide (TiAlO), tantalum aluminum oxide (TaAlO), titanium silicon oxide (TiSiO), or tantalum silicon oxide (TaSiO) may be used as a material of the first lower hydrogen barrier film 210. Moreover, it is effective to set the thickness of the first lower hydrogen barrier film 210 to about 5 nm to about 200 nm.

Next, as shown in FIG. 7D, a titanium aluminum nitride film, an iridium film, an iridium oxide film, and a platinum film, each having a thickness of about 50 nm, are sequentially formed over the whole substrate surface including the first lower hydrogen barrier film 210 and the second contact plugs 209 by, for example, a sputtering method. Then, the laminated film formed is patterned by a lithography method and a dry etching method so as to leave the regions of the laminated film, which are located near the second contact plugs 209, thereby forming second lower hydrogen barrier films 211 made of titanium aluminum nitride, and lower electrodes 212 including the iridium film, the iridium oxide film, and the platinum film. Thus, the conductive second lower hydrogen barrier films 211 are respectively positioned directly under the lower electrodes 212, and the first lower hydrogen barrier film 210 covers the lower side of each lower electrode 212 in a region which surrounds the lower electrode 212 when viewed in plan. Note that, since the first lower hydrogen barrier film 210 is partially etched when forming the second lower hydrogen barrier films 211, the thickness of the first lower hydrogen barrier film 210 becomes smaller than about 100 nm. Moreover, although titanium aluminum nitride having a thickness of about 50 nm was used as the second lower hydrogen barrier films 211, titanium silicon nitride (TiSiN), tantalum nitride (TaN), tantalum silicon nitride (TaSiN), tantalum aluminum nitride (TaAlN), or tantalum aluminum (TaAl) may alternatively be used as the second lower hydrogen barrier films 211. Moreover, it is effective to set the thickness of the second lower hydrogen barrier films 211 to about 5 nm to about 200 nm.

Moreover, although a laminated film of an iridium film, an iridium oxide film, and a platinum film, each having a thickness of about 50 nm, was used as the lower electrodes 212, a combination of an iridium oxide film or a ruthenium oxide (RuO₂) film, having a thickness of about 50 nm to about 300 nm, and the like may alternatively be used as the lower electrodes 212. Alternatively, a laminated film of a ruthenium film and a ruthenium oxide film, formed sequentially from bottom to top, and each having a thickness of about 50 nm to about 300 nm, may be used as the lower electrodes 212. Alternatively, the lower electrodes 212 may be formed by a laminated film including at least two of the single-layer films and the laminated films described above.

Moreover, although a CVD method was used to form the first lower hydrogen barrier film 210, and a sputtering method was used to form the second lower hydrogen barrier films 211 in the manufacturing method of the present embodiment, the present invention is not limited to these. For example, a sputtering method may be used to form the first lower hydrogen barrier film 210, and a CVD method may be used to form the second lower hydrogen barrier films 211.

Next, as shown in FIG. 7E, a silicon oxide film is formed over the whole surface of the first lower hydrogen barrier film 210 by a CVD method so as to embed the lower electrodes 212. Then, the silicon oxide film is polished by a CMP method until the upper surfaces of the lower electrodes 212 are exposed. Thus, a third interlayer insulating film 216 is formed between adjacent lower electrodes 212 so that the upper surface of the third interlayer insulating film 216 becomes flush with the upper surfaces of the lower electrodes 212. Silicon oxide such as BPSG, HDP-NSG, O₃-NSG, or the like can be similarly used as a constituent material of the third interlayer insulating film 216. Moreover, in order to expose the lower electrodes 212, silicon oxide, having a thickness in the range of more than 0 nm up to about 100 nm, may be left on the lower electrodes 212 by a CMP method, and a dry etching method or a wet etching method may be used thereafter.

Then, a film of a ferroelectric material having a bismuth laminar perovskite structure, that is, a film of SrBi₂(Ta_{1-N}Nbₓ), is formed with a thickness of about 50 nm to about 150 nm on the lower electrodes 212 and the third interlayer insulating film 216 by a MOD (Metal-Organic Decomposition) method, a MOCVD (Metal Organic Chemical Vapor Deposition) method, a sputtering method, or a coating method. Then, the platinum film and the ferroelectric film are patterned to form capacitive insulating films 213 made of the ferroelectric film, and upper electrodes 214 made of platinum. Capacitors 215, which are formed by the lower electrodes 212, the capacitive insulating films 213, and the upper electrodes 214, are formed in this manner.

A ferroelectric material, which is a bismuth laminar perovskite oxide, such as the general formula Pb(ZrₓT₁₋ₓ)O₃, (BaₓSr₁₋ₓ)TiO₃, or (BiₓLa₁₋ₓ)₄Ti₃O₁₂ (where x is 0≦x≦1 in each formula) can be used as a constituent material of the capacitive insulating films 213. Alternatively, tantalum pentoxide (Ta₂O₅) as a high-k material may be used.

Next, as shown in FIG. 7F, a fourth interlayer insulating film 217, made of silicon oxide, is formed by a CVD method on the whole substrate surface including the third interlayer insulating film 216 and the upper electrodes 214 of the capacitors 215. Then, a portion of the fourth interlayer insulating film 217, the third interlayer insulating film 216, and the first lower hydrogen barrier film 210, which is located outside the memory region, is removed by a lithography method and a dry etching method. In this step, a portion of the fourth interlayer insulating film 217 and the third interlayer insulating film 216, which is formed above a region other than the memory region in the semiconductor substrate 201, is removed so as to leave a portion formed above the memory region. At this time, the side surfaces (the end faces) of the second interlayer insulating film 208, the third interlayer insulating film 216, and the fourth interlayer insulating film 217 are tapered in the upward direction toward the inside of the memory region.

Then, an upper hydrogen barrier film 218, made of titanium aluminum oxide, is formed with a thickness of about 50 nm on the upper and side surfaces of the fourth interlayer insulating film 217, on the side surface of the third interlayer insulating film 216, and on the side surface of the first lower hydrogen barrier film 210, by a sputtering method. Thus, the upper hydrogen barrier film 218 is directly connected to (in direct contact with) the first lower hydrogen barrier film 210 in the region surrounding the capacitors 215 when viewed from above (on the peripheral portion in the memory region). Then, an unnecessary portion of the upper hydrogen barrier film 218, which is formed on the peripheral circuit region, is removed by a lithography method and a dry etching method. Silicon oxide, such as BPSG, HDP-NSG, O₃-NSG, or the like can be similarly used as a constituent material of the fourth interlayer insulating film 217. Moreover, the fourth interlayer insulating film 217 may have a thickness of about 50 nm to about 500 nm on the upper electrodes 214. Note that, although a titanium aluminum oxide film having a thickness of about 50 nm was used as the upper hydrogen barrier film 218, the present invention is not limited to this. The upper hydrogen barrier film 218 may be made of silicon nitride, silicon oxynitride, aluminum oxide, tantalum aluminum oxide, titanium silicon oxide, or tantalum silicon oxide. Note that the upper hydrogen barrier film 218 provides sufficient barrier characteristics against hydrogen when it has a thickness of about 5 nm to about 200 nm.

Then, as shown in FIG. 7G, a silicon oxide film is formed by a CVD method on the whole substrate surface including the upper hydrogen barrier film 218 and the first interlayer insulating film 205. Then, the silicon oxide film is planarized by a CMP method to form a fifth interlayer insulating film 219. Contact holes, which expose the impurity diffusion layers 203a extending from the peripheral portion in the memory region to the peripheral circuit region, and formed in the boundary region between the memory region and the peripheral circuit region, are selectively formed on a region of the fifth interlayer insulating film 219, which is located outside the memory region. Then, by a CVD method, a titanium film having a thickness of about 10 nm, a titanium nitride film having a thickness of about 20 nm, and a tungsten film having a thickness of about 300 nm are sequentially formed on the fifth interlayer insulating film 219 so as to fill the contact holes. Then, a portion of the formed films, which is located on the upper surface of the fifth interlayer insulating film 219, is removed by a CMP method to form third contact plugs 220 respectively connected to the impurity diffusion layers 203a. Then, by a sputtering method, a titanium film having a thickness of about 10 nm, a titanium nitride film having a thickness of about 50 nm, an aluminum film having a thickness of about 500 nm, and a titanium nitride film having a thickness of about 50 nm, are sequentially formed on the fifth interlayer insulating film 219 and the third contact plugs 220. Then, the laminated film formed is patterned by a dry etching method to form interconnects 221, which are made of a part of the laminated film, and are respectively connected to the third contact plugs 220. Silicon oxide such as BPSG, HDP-NSG, O₃-NSG, or the like can be similarly used as a constituent material of the fifth interlayer insulating film 219. Moreover, when planarizing the fifth interlayer insulating film 219, the fifth interlayer insulating film 219 may have a thickness of about 50 nm to about 300 nm on the upper hydrogen barrier film 218.

Then, although not shown in the figures, known manufacturing processes, such as formation of multilayer interconnects, formation of a protective film, formation of pads, and the like, are performed to obtain a desired semiconductor memory device.

According to the semiconductor memory device of the present embodiment obtained as described above, as an interconnection method for drawing the potential of the bit lines 207, formed in a lower layer than that of the capacitors 215, onto the peripheral circuit region, the potential of the bit lines 207 is drawn via the conductive layers which are formed in a lower layer than that of the bit lines 207. This prevents reduction in film thickness of the bit lines 207, which is very likely to occur in a conventional interconnection method for directly drawing the potential from the bit lines in the upward direction. Thus, the semiconductor memory devices, which cause no malfunction resulting from a variation in resistance of the bit lines 207 due to reduction in film thickness of the bit lines 207, can be stably manufactured and provided. Note that, when the impurity diffusion layers 203a, or the electrode layers positioned in the same layer as that of the gate electrode 204 (see FIG. 4), are used as the conductive layers connected to the bit lines 207, reliability of the semiconductor memory device can be improved without increasing the number of manufacturing steps.

As described above, the present invention is useful for improving reliability of semiconductor memory devices having, for example, a COB structure.

The foregoing description illustrates and describes the present disclosure. Additionally, the disclosure shows and describes the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

What is claimed is:

1. A semiconductor memory device, comprising:
a semiconductor substrate in which a memory region, and a peripheral circuit region adjacent to the memory region, are formed;
a MOS transistor formed on the memory region, and having a gate electrode formed over the semiconductor substrate, and first and second impurity diffusion layers formed in regions which are located on both lateral sides of the gate electrode in an upper part of the semiconductor substrate;
a bit line provided above the memory region, and electrically connected to the first impurity diffusion layer;
a capacitor which includes a lower electrode, an upper electrode, and a capacitive insulating film interposed between the lower electrode and the upper electrode, and including a ferroelectric material or a high-k material, the capacitor being provided above the memory region at a position higher than that of the bit line;
a lower hydrogen barrier film which is formed between the bit line and the capacitor, and covers a lower side of the capacitor;
an upper hydrogen barrier film which covers lateral and upper sides of the capacitor, and is directly connected to the lower hydrogen barrier film in a region which surrounds the capacitor when viewed from above;
a first interconnect formed above the peripheral circuit region; and
a conductive layer which is formed at a position lower than that of the bit line, and extends from the memory region to the peripheral circuit region when viewed from above, for electrically connecting the bit line and the first interconnect to each other.

2. The semiconductor memory device of claim 1, wherein
multiple ones of the capacitor are provided, and arranged in a matrix pattern over the memory region, and
the lower hydrogen barrier film and the upper hydrogen barrier film collectively surround all of the multiple ones of the capacitor.

3. The semiconductor memory device of claim 1, wherein
the conductive layer is a third impurity diffusion layer formed in the upper part of the semiconductor substrate.

4. The semiconductor memory device of claim 1, wherein
the conductive layer is a second interconnect provided at a position lower than that of the bit line.

5. The semiconductor memory device of claim 1, wherein
the conductive layer is an electrode interconnect formed in a same layer as that of the gate electrode.

6. The semiconductor memory device of claim 1, further comprising:
an interlayer insulating film formed on lateral and upper sides of the capacitor, wherein
a groove is formed in a portion of the interlayer insulating film, which is located above a boundary region between the memory region and the peripheral circuit region, and
the upper hydrogen barrier film is formed so as to extend from an upper surface of the interlayer insulating film to an inner surface of the groove.

7. The semiconductor memory device of claim 1, wherein
the lower electrode is electrically connected to the second impurity diffusion layer.

8. The semiconductor memory device of claim 1, wherein
the lower hydrogen barrier film is made of an insulating material.

9. The semiconductor memory device of claim 1, wherein
the upper hydrogen barrier film and the lower hydrogen barrier film are in contact with each other at a position right above the conductive layer.
